(19) United States
(12) Patent Application Publication
(10) Pub. No.: US 2002/0142596 A1
(43) Pub. Date: Oct. 3, 2002

(54) Method for selectively etching silicon and/or metal silicides

(75) Inventor: Tinghao F. Wang, Fremont, CA (US)

Correspondence Address: BRINKS HOFER GILSON & LIONE, P.O. Box 10395, Chicago, IL, 60610, US

(73) Assignee: Cypress Semiconductor Corporation

(21) Appl. No.: 10/071,809

(22) Filed: Feb. 7, 2002

Related U.S. Application Data
(63) Continuation of application No. 09/342,335, filed on Jun. 29, 1999.

(51) Int. Cl. H01L 21/302

(52) U.S. Cl. 438/689

(57) ABSTRACT

A metal silicide (e.g., WSiₓ) layer an integrated circuit is etched in a Cl₂/O₂ environment having an O₂ concentration of greater than or equal to 25% by volume. This environment may be provided at a pressure of approximately 2-40 mili-Torr, in a reactor with a source power of approximately 200-2000 Watts and a bias power of approximately 30-400 Watts for approximately 30 seconds. In one particular example, the Cl₂/O₂ environment includes approximately 45 sccm Cl₂ and 30 sccm O₂. The metal silicide layer is fully etched without etching an underlying poly-silicon layer. The metal silicide layer may be a portion of a gate structure.

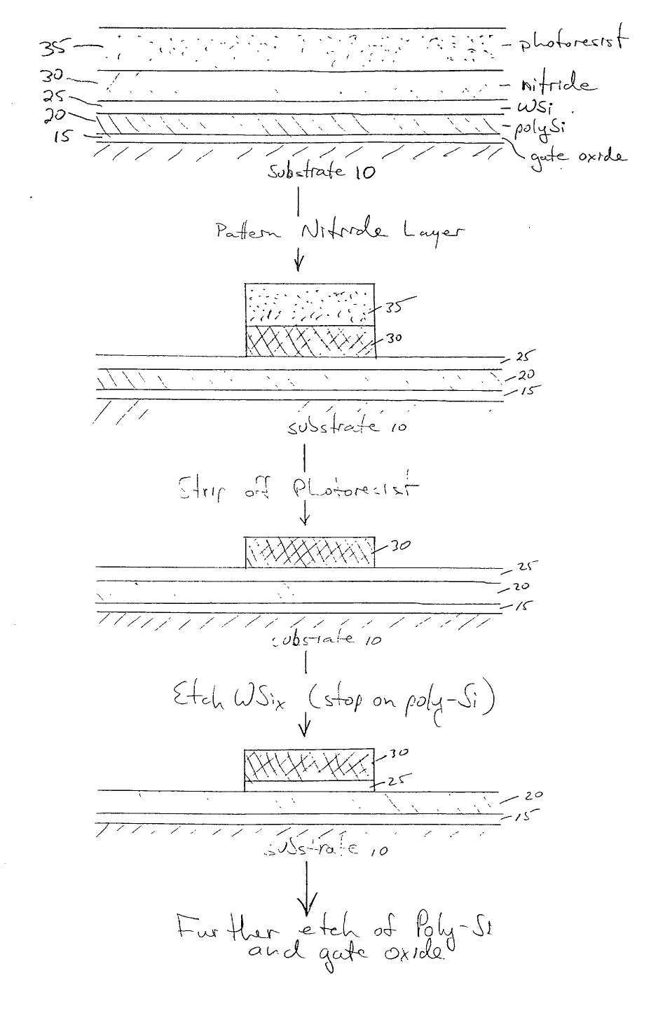

### FIELD OF THE INVENTION

The present invention relates to the field of semiconductor device manufacturing processes and, in particular, to a tungsten silicide, chromium silicide and/or titanium silicide etch chemistry that is highly selective to poly-silicon and gate oxide structures.

### BACKGROUND

One of the challenges facing designers of integrated circuits and other semiconductor devices is the need to continually reduce feature size dimensions so as to be able to improve feature densities on semiconductor (or other) wafers and/or dies. For example, one means by which feature density on a die has been improved is through the use of narrow gate electrodes with a tungsten silicide (WSiₓ)/poly-Si stack structure. Such a gate structure provides a good poly/SiO₂ interface, good thermal stability and low contact resistance.

However, forming such a narrow gate structure with a vertical profile and no trenching through the thin gate dielectric that lies beneath the WSiₓ/poly-Si stack presents a significant challenge for dry etch processes. That is, the etch should be perfectly anisotropic so as to minimize the critical dimension loss and should exhibit high selectivity to the underlying gate oxide. In many cases, fluorine-based etching gases have been used for WSiₓ/poly-Si etching because such chemistries provide a high etch rate for the WSiₓ. However, these chemistries present a problem because they tend to exhibit a large amount of side etching and low selectivity to the gate oxide. Chlorine-based etching gases provide reduced side etching and higher selectivity to SiO₂, however, the etch rate of the WSiₓ is slower than that for fluorine-based chemistries.

In the past, some reported studies have shown that plasma etch using a Cl₂/O₂ gas mixture, with low concentrations of O₂ (i.e., less than 15% O₂ by volume) have exhibited improved WSiₓ etch rate, and such chemistries were found to exhibit high poly-Si/SiO₂ selectivity. However, these same studies reported that as the O₂ concentration increased above approximately 20%, the WSiₓ and ploy-Si etch rates were dramatically reduced. Indeed, the studies report that the etching stops when the O₂ concentration exceeds 25%. See, e.g., Kazuo Nojiri et al., “High Rate and Highly Selective Anisotropic Etching for WSix/Poly-Si Using Electron Cyclotron Resonance Plasma,” J. Vac. Sci. Technol. B 14(3) May/June 1996. Also, the etch was not selective between the WSiₓ and the poly-Si.

### SUMMARY OF THE INVENTION

In one embodiment, a metal silicide (e.g., WSiₓ) layer is etched during fabrication of an integrated circuit in a Cl₂/O₂ environment having an O₂ concentration of greater than or equal to 25% (e.g., 25-75%) by volume. This environment may be provided at a pressure of approximately 2-40 mili-Torr, in a reactor with a source power of approximately 200-2000 (and in one example 400) Watts and a bias power of approximately 35 to 400 (and, in one example 50) Watts for approximately 30 seconds. In one particular example, 9 the Cl₂/O₂ environment includes approximately 45 sccm Cl₂ and 30 sccm O₂.

In a further embodiment, a metal silicide layer is etched during fabrication of an integrated circuit in an environment having a high concentration of O₂ so as to fully etch the WSiₓ layer without etching an underlying poly-silicon layer. Preferably, the O₂ concentration is greater than or equal to 25% by volume.

In another embodiment, an integrated circuit includes a metal silicide layer etched within an environment that provides high selectivity to poly-silicon, for example an environment that includes a concentration of O₂ of at least 25% by volume (e.g., 45 sccm Cl₂ and 30 sccm O₂). The metal silicide layer may be a portion of a gate structure.

### BRIEF DESCRIPTION OF THE DRAWINGS

The present invention is illustrated by way of example, and not limitation, in the accompanying figure, which illustrates various steps during the fabrication of an integrated circuit (e.g., a gate structure therein) in accordance with an embodiment of the present invention.

### DETAILED DESCRIPTION

An etch chemistry for tungsten silicide, chromium silicide and/or titanium silicide that is highly selective to poly-silicon and gate oxide structures is disclosed herein. Although discussed with reference to certain illustrated embodiments, upon review of this specification, those of ordinary skill in the art will recognize that the present methods may find application in a variety of systems. For example, much of the following discussion will focus on a WSiₓ etch, but it should be recognized that the techniques are equally applicable to a chromium silicide or titanium silicide etch. Therefore, in the following description the illustrated embodiments should be regarded as exemplary only and should not be deemed to be limiting in scope.

Through experiment, it has been determined that a Cl₂/O₂-based etch chemistry wherein the O₂ concentration is greater than or equal to 25% (e.g., 25-75%) by volume provides a WSiₓ etch that is highly selective (e.g., a ratio of etch rates on the order of 30 or more) to poly-silicon, silicon, nitride and oxides (e.g., gate oxides). Indeed, oxide and nitride selctivities on the order of 100 or more have been observed. To more fully appreciate the present etch process, one should make reference to the layer structure presented in the accompanying figure.

As shown in the upper illustration of the figure, in creating gate structures a gate oxide layer 15 is grown (e.g., through thermal oxidation) over a substrate 10. Such gate oxide layers may be from 25-70 Å thick. Next, a poly-Si layer 20 of approximately 1000 Å is depositied over the oxide and a WSiₓ layer 25 of approximately 1000 Å is deposited thereover. On top of the WSiₓ layer 25, a nitride mask layer 30 (e.g., approximately 2000 Å thick) is deposited and patterned through the use of a conventional photoresist layer 35.

After patterning, the photoresist layer 35 is stripped off (see the second and third illustrations in sequence) and the etch of the WSiₓ layer 25 can be commenced. The goal of this etch is to completely remove the WSiₓ (except in those areas under the nitride mask) without etching the underlying poly-Si layer 20. As can bee seen from the Nojiri article cited above, previous etch chemistries did not allow for the control of this etch so as to stop on the poly-Si. In other words, these previous etch chemistries were not selective between WSiₓ and poly-Si.

The present etch chemistry, however, does provide a high degree of selectivity between WSiₓ and poly-Si. As indicated above, a ratio of etch rates in WSiₓ and poly-Si of 30:1 or more has been observed. This provides the high degree of selectivity needed to ensure that the etch can be stopped on the poly-Si layer 20 as desired. Afterwards, a conventional poly-Si etch and gate oxide removal process can be used to finish forming the gate structure.

The present WSiₓ etch employs a Cl₂/O₂ chemistry, with a high concentration (e.g., greater than or equal to 25%, for example 25-75%, by volume) of O₂. Contrary to the results reported by Nojiri, under the present etch conditions it has been observed that even in such high O₂ concentration, WSiₓ is etched. In one example, the etch was performed using a LAM 9400 high density plasma reactor, available from LAM Research of Fremont, Calif. Prior to the Cl₂/O₂ etch, a brief (e.g., approximately 5 second) breakthrough etch using CF₄ was performed. Then, the Cl₂/O₂ etch was performed at a pressure of approximately 3 mili-Torr (mT) (or, more generally, a low pressure of approximately 2-40 mT), a source power of approximately 400 W (or, more generally, approximately 200-2000 W), a bias power of approximately 35 to 400 (e.g., 50) W, in an environment of approximately 45 sccm Cl₂ and 30 sccm O₂ for approximately 30 seconds. Note that in practice the etch time may vary depending on the film thickness. Under the above conditions, a WSiₓ etch rate of approximately 1639 Å/min was observed. The WSiₓ layer (approximately 1000 Å) was completely etched, while the underlying poly-Si layer was not etched to an observable degree.

The present etch chemistry for WSiₓ provides an improved process window (over that provided by schemes of the past) for structures wherein WSiₓ overlies a poly-Si layer. For example, the present etch process may be used during the patterning of gate structures or other structures during the fabrication of integrated circuit devices.

Thus a tungsten silicide etch chemistry that is highly selective to poly-silicon and gate oxide structures has been described. Although the foregoing description and accompanying figures discuss and illustrate specific embodiments, it should be appreciated that the present invention is to be measured only in terms of the claims that follow.

What is claimed is:

1. A method comprising, etching a metal silicide layer during fabrication of an integrated circuit in a Cl₂/O₂ environment having an O₂ concentration of greater than or equal to 25% by volume.

2. The method of claim 1 wherein the Cl₂/O₂ environment is provided at a pressure of approximately 2-40 mili-Torr.

3. The method of claim 2 wherein the pressure is approximately 3 mili-Torr.

4. The method of claim 1 wherein the Cl₂/O₂ environment is provided in a reactor with a source power of approximately 200-2000 Watts.

5. The method of claim 4 wherein the source power is approximately 400 Watts.

6. The method of claim 1 wherein the Cl₂/O₂ environment is provided in a reactor having a bias power of approximately 35 to 400 Watts.

7. The method of claim 6 wherein the reactor has a bias power of approximately 50 Watts.

8. The method of claim 1 wherein the metal silicide layer is a tungsten silicide layer.

9. The method of claim 1 wherein the Cl₂/O₂ environment comprises approximately 45 sccm Cl₂ and 30 sccm O₂.

10. The method of claim 9 wherein the Cl₂/O₂ environment is provided for a time period sufficient to completely etch the metal silicide layer.

11. The method of claim 9 wherein the time period is approximately 30 seconds.

12. A method comprising etching a metal silicide layer during fabrication of an integrated circuit in an environment having a high concentration of O₂ so as to fully etch the metal silicide layer without etching an underlying poly-silicon layer.

13. The method of claim 12 wherein the O₂ concentration is greater than or equal to 25% by volume.

14. The method of claim 12 wherein the environment comprises approximately 45 sccm Cl₂ and 30 sccm O₂.

15. The method of claim 12 wherein the metal silicide is chosen from the group consisting of tungsten silicide, chromium silicide and titanium silicide.

16. An integrated circuit comprising a metal silicide layer etched within an environment that provides high selectivity to poly-silicon.

17. The integrated circuit of claim 16 wherein the environment comprises a concentration of O₂ of at least 25% by volume.

18. The integrated circuit of claim 17 wherein the environment comprises a concentration of approximately 45 sccm Cl₂ and 30 sccm O₂.

19. The integrated circuit of claim 16 wherein the environment comprises a Cl₂/O₂ environment having a concentration of O₂ of at least 25% by volume.

20. The integrated circuit of claim 16 wherein the metal silicide layer comprises a portion of a gate structure.
